(19) United States
(12) Patent Application Publication
(10) Pub. No.: US 2022/0293438 A1
(43) Pub. Date: Sep. 15, 2022

(54) PROCESSING APPARATUS AND PROCESSING METHOD

(71) Applicant: DISCO CORPORATION, Tokyo (JP)

(72) Inventor: Yoshitomo NARITA, Tokyo (JP)

(21) Appl. No.: 17/652,722

(22) Filed: Feb. 28, 2022

(30) Foreign Application Priority Data
Mar. 12, 2021 (JP) 2021-040098

(51) Int. Cl. H01L 21/67

(52) U.S. Cl. CPC H01L 21/67092

(57) ABSTRACT

A processing trajectory at the time of processing a peripheral part of a workpiece is set such that a processing width of the peripheral part of the workpiece is narrowed as spaced more from the position of a notch in a predetermined range centered at the position of the notch and that the processing width of the peripheral part of the workpiece is equal to a reference width (lower limit of the processing width) outside the predetermined range. As a result, the processing width at a position far from the position of the notch is narrow, and therefore, the proportion of devices damaged by edge trimming can be reduced or set to zero. In addition, since the processing width at the position of the notch is widened most, the probability that cracks are generated in the workpiece after the back surface side of the workpiece is ground can be lowered.

### BACKGROUND OF THE INVENTION

### Field of the Invention

The present invention relates to a processing apparatus for processing a disk-shaped workpiece formed with a notch and a processing method for processing the workpiece.

### Description of the Related Art

Chips of devices such as integrated circuits (ICs) and large scale integration (LSI) circuits are constituent elements indispensable to various electronic appliances such as mobile phones and personal computers. Such chips are manufactured, for example, by forming a multiplicity of devices on a front surface of a workpiece such as a semiconductor wafer, and thereafter dividing the workpiece into regions including respective devices.

The workpiece used for manufacture of chips is liable to be broken with a crack generated at a peripheral part thereof as a starting point. Therefore, in the manufacturing process of chips, prior to various steps, the peripheral part of the workpiece is generally chamfered. Further, in the manufacturing process of chips, for the purpose of reducing the size of the chips to be manufactured, for example, the workpiece is often ground on the back surface side thereof to be thinned prior to division of the workpiece.

It is to be noted, however, that, when the workpiece chamfered at the peripheral part thereof is ground on the back surface side thereof to be thinned, the peripheral part on the back surface side of the workpiece becomes like a knife edge. At the peripheral part, stress is concentrated, and cracks are liable to be generated. Therefore, in the manufacturing process of chips, after edge trimming for removing a part on the front surface side of the peripheral part is carried out, the back surface side of the workpiece may be ground in such a manner as to remove the remainder of the peripheral part (see, for example, Japanese Patent Laid-open 2000-173961).

In addition, at the peripheral part of the workpiece used for manufacture of chips, generally, a notch indicative of the crystal orientation of the workpiece is formed. This notch is used, for example, for positioning of the workpiece in the manufacturing process of chips. It is to be noted, however, that, when edge trimming and grinding of the back surface side are carried out on such a workpiece, the notch may disappear, and it may become difficult to position the workpiece in subsequent steps.

In consideration of this point, a method of edge trimming in which the crystal orientation of the workpiece can be recognized even after grinding of the back surface side of the workpiece has been proposed (see, for example, Japanese Patent Laid-open No. 2019-220632). In this method, edge trimming is carried out on the workpiece such that the front surface of the workpiece becomes elliptic. Specifically, the front surface is processed such that the direction of the notch as viewed from the center of the workpiece coincides with the direction of the short axis of the ellipse.

### SUMMARY OF THE INVENTION

In order to reduce the manufacturing cost of chips, it is preferable to form as many devices as possible on the front surface of the workpiece. In such a case, for reducing the proportion of devices damaged by edge trimming or setting the proportion to zero, it is preferable to narrow the processing width of edge trimming as much as possible.

On the other hand, when the processing width of edge trimming is narrowed, a part of the notch may remain on the front surface side of the workpiece. In this case, cracks may be generated due to remaining of a tip part of the notch (a part closer to the center of the workpiece) on the front surface side of the workpiece, after the back surface side of the workpiece having undergone edge trimming is ground.

In view of this, it is an object of the present invention to provide a processing apparatus and a processing method by which the proportion of devices damaged by edge trimming can be reduced or set to zero, and the probability that cracks are generated in the workpiece after the back surface side of the workpiece is ground can be lowered.

In accordance with an aspect of the present invention, there is provide a processing apparatus for processing a disk-shaped workpiece formed with a notch, the processing apparatus including a holding table that holds the workpiece, a processing unit that processes the workpiece held by the holding table, and a control unit that controls the processing unit in such a manner as to process a peripheral part of the workpiece with a processing width equal to or more than a reference width along an annular processing trajectory. The processing trajectory is set such that the processing width of the peripheral part of the workpiece is narrowed as spaced more from a position of the notch in a predetermined range including the position of the notch and that the processing width of the peripheral part of the workpiece is equal to the reference width outside the predetermined range.

Preferably, the processing apparatus of the present invention further includes an input unit through which to input information for setting the processing trajectory to the control unit, and the information includes an increase width of the processing width from the reference width at the position of the notch and the predetermined range.

Further, preferably, in the processing apparatus of the present invention, the processing unit has an annular cutting blade attached to a spindle.

Alternatively, preferably, in the processing apparatus of the present invention, the processing unit has a laser oscillator that generates a laser beam of such a wavelength as to be absorbed in the workpiece.

Alternatively, preferably, in the processing apparatus of the present invention, the processing unit has a laser oscillator that generates a laser beam of such a wavelength as to be transmitted through the workpiece.

In accordance with another aspect of the present invention, there is provided a processing method for processing a disk-shaped workpiece formed with a notch, the processing method including a holding step of holding the workpiece by a holding table, and a processing step of processing a peripheral part of the workpiece with a processing width equal to or more than a reference width along an annular processing trajectory. The processing trajectory is set such that the processing width of the peripheral part of the workpiece is narrowed as spaced more from a position of the notch in a predetermined range including the position of the notch and that the processing width of the peripheral part of the workpiece is equal to the reference width outside the predetermined range.

In the present invention, the processing trajectory at the time of processing the peripheral part of the workpiece is set such that the processing width of the peripheral part of the workpiece is narrowed as spaced more from the position of the notch in the predetermined range including the position of the notch and that the processing width of the peripheral part of the workpiece is equal to the reference width (lower limit of the processing width) outside the predetermined range.

As a result, in the present invention, the processing width at a position far from the position of the notch is narrow, and therefore, the proportion of devices damaged by edge trimming can be reduced or set to zero. In addition, in the present invention, since the processing width at the position of the notch is widened most, the probability that cracks are generated in the workpiece after the back surface side of the workpiece is ground can be lowered.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically depicting an example of a processing apparatus;

FIG. 2A is a top plan view schematically depicting an example of a workpiece;

FIG. 2B is a sectional view schematically depicting the example of the workpiece;

FIG. 3 is a diagram schematically depicting an example of an input screen for inputting information necessary to set a processing trajectory of edge trimming to be carried out on the workpiece;

FIG. 4 is a flow chart schematically depicting an example of a processing method for the workpiece;

FIG. 5 is a top plan view schematically depicting the workpiece placed on a holding table;

FIG. 6 is a diagram schematically depicting an example of the input screen on which information necessary to set the processing trajectory of edge trimming to be carried out on the workpiece has been inputted;

FIG. 7 is a top plan view schematically depicting a relation between an inner circumference of the processing trajectory of edge trimming and the position of the workpiece;

FIG. 8A is a top plan view schematically depicting the workpiece undergoing edge trimming;

FIG. 8B is a sectional view schematically depicting the workpiece undergoing edge trimming;

FIG. 9A is a top plan view schematically depicting the workpiece undergoing edge trimming;

FIG. 9B is a sectional view schematically depicting the workpiece undergoing edge trimming;

FIG. 10A is a top plan view schematically depicting the workpiece undergoing edge trimming;

FIG. 10B is a sectional view schematically depicting the workpiece undergoing edge trimming;

FIG. 11A is a top plan view schematically depicting the workpiece undergoing edge trimming;

FIG. 11B is a sectional view schematically depicting the workpiece undergoing edge trimming;

FIG. 12A is a top plan view schematically depicting the workpiece undergoing edge trimming;

FIG. 12B is a sectional view schematically depicting the workpiece undergoing edge trimming;

FIG. 13A is a top plan view schematically depicting the workpiece having undergone edge trimming;

FIG. 13B is a side view schematically depicting the workpiece having undergone edge trimming; and

FIG. 14 is a perspective view schematically depicting an example of a laser applying apparatus.

### DETAILED DESCRIPTION OF THE PREFERRED EMBODIMENTS

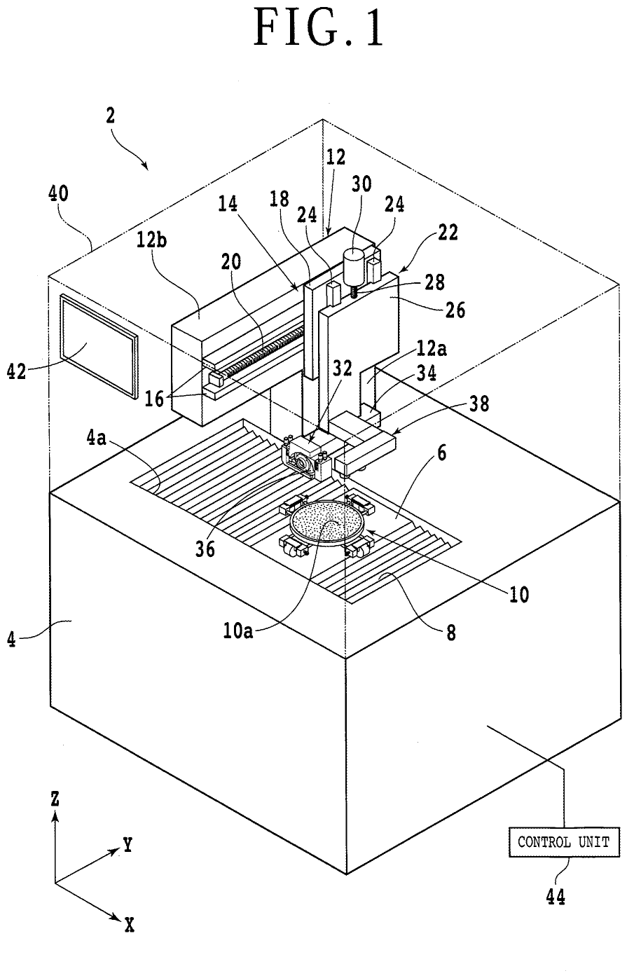

Embodiments of the present invention will be described referring to the attached drawings. FIG. 1 is a perspective view schematically depicting an example of a cutting apparatus as a processing apparatus for processing a workpiece. Note that an X-axis direction (front-rear direction) and a Y-axis direction (left-right direction) depicted in FIG. 1 are directions orthogonal to each other on a horizontal plane, and a Z-axis direction (upward-downward direction) is a direction (vertical direction) orthogonal to the X-axis direction and the Y-axis direction. In addition, in FIG. 1, for convenience' sake, part of the constituent elements of the cutting apparatus is depicted in a block.

The cutting apparatus 2 depicted in FIG. 1 includes a base 4 that supports each constituent element. A rectangular opening 4a of which the longitudinal direction is parallel to the X-axis direction is formed on an upper surface of the base 4. In the opening 4a, there are provided a flat plate-shaped cover 6 and a bellows-like cover 8 that is contracted and extended attendant on movement of the cover 6.

On an upper side of the cover 6, a holding table 10 is provided. The holding table 10 has a disk-shaped porous plate 10a exposed to the upper side. An upper surface of the porous plate 10a is substantially flat, and becomes a holding surface of the holding table 10 that holds the workpiece thereon. On a lower side of the covers 6 and 8, there is provided an X-axis direction moving mechanism (not illustrated) that moves the cover 6 and the holding table 10 in the X-axis direction.

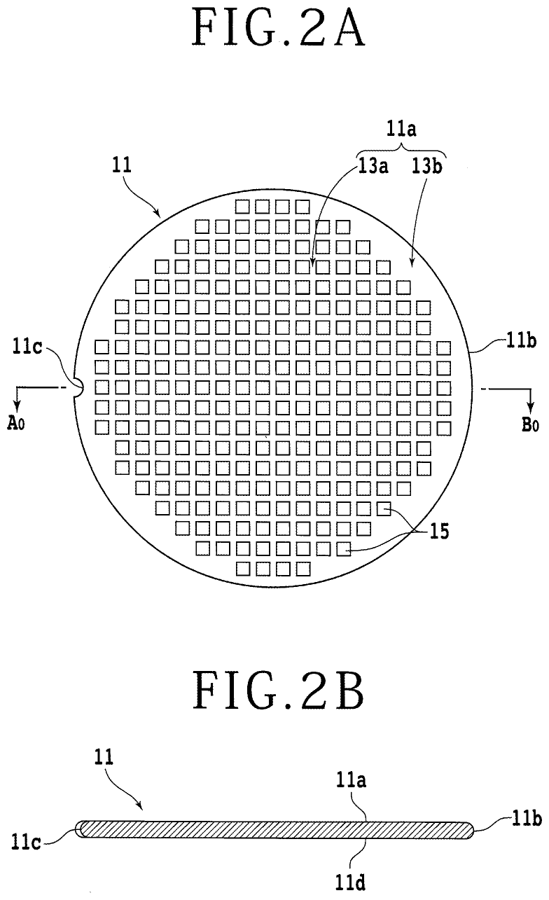

FIG. 2A is a top plan view schematically depicting an example of the workpiece held on the holding surface of the holding table 10, and FIG. 2B is a sectional view schematically depicting a section of the workpiece, taken along line A₀B₀ depicted in FIG. 2A. The workpiece 11 depicted in FIGS. 2A and 2B is, for example, a wafer formed from a semiconductor material such as silicon (Si), silicon carbide (SiC), or gallium nitride (GaN).

A front surface 11a of the workpiece 11 includes a device area 13a and a peripheral marginal area 13b surrounding the device area 13a. The device area 13a is partitioned into a plurality of regions by a plurality of scheduled dividing lines set in a grid pattern, and devices 15 such as ICs and LSI circuits are formed in the respective regions.

In addition, a peripheral part of the workpiece 11 is chamfered. In other words, a side surface 11b of the workpiece 11 is curved to be projected outward. Besides, the peripheral part of the workpiece 11 is formed with a notch 11c indicative of crystal orientation of the workpiece 11. The workpiece 11 has its back surface 11d side placed on the holding surface of the holding table 10 (on the upper surface of the porous plate 10a), either directly or through a dicing tape (not illustrated).

Note that, inside the holding table 10, there is formed a suction passage (not illustrated) having one end connected to a suction source (not illustrated) such as an ejector provided outside the holding table 10. The other end of the suction passage reaches the porous plate 10a. Therefore, when the suction source is operated in a state in which the workpiece 11 is placed on the holding surface with the back surface 11d set on the lower side, the workpiece 11 is held by the holding table 10 under suction.

Further, the holding table 10 is connected to a holding table rotational drive source (not illustrated) such as a motor. When the holding table rotational drive source is operated, the holding table 10 is rotated around a rotational axis which passes the center of the holding surface and which extends along the Z-axis direction.

In the vicinity of the opening 4a in the upper surface of the base 4, a support structure 12 is provided. The support structure 12 includes an upright section 12a extending along the Z-axis direction from the upper surface of the base 4, and an arm section 12b extending along the Y-axis direction from an upper end part of the upright section 12a in such a manner as to bridge a space above the opening 4a. On a front surface side of the arm section 12b, a Y-axis direction moving mechanism 14 is provided.

The Y-axis direction moving mechanism 14 includes a pair of Y-axis guide rails 16 which are fixed to the front surface of the arm section 12b and extend along the Y-axis direction. A Y-axis moving plate 18 is connected to a front surface side of the pair of Y-axis guide rails 16 in such a manner as to be slidable along the pair of Y-axis guide rails 16.

In addition, a screw shaft 20 extending along the Y-axis direction is disposed between the pair of Y-axis guide rails 16. A motor (not illustrated) for rotating the screw shaft 20 is connected to one end part of the screw shaft 20. On a surface of the screw shaft 20 formed with a spiral groove, a nut section (not illustrated) for accommodating a ball that rolls on the surface of the rotating screw shaft 20 is provided, to constitute a ball screw.

In other words, when the screw shaft 20 is rotated, the ball is circulated in the nut section, and the nut section is moved along the Y-axis direction. In addition, the nut section is fixed to a back surface side of the Y-axis moving plate 18. Therefore, when the screw shaft 20 is rotated by the motor connected to one end part of the screw shaft 20, the Y-axis moving plate 18 is moved along the Y-axis direction together with the nut section.

On a front surface side of the Y-axis moving plate 18, a Z-axis direction moving mechanism 22 is provided. The Z-axis direction moving mechanism 22 includes a pair of Z-axis guide rails 24 which are fixed to the front surface of the Y-axis moving plate 18 and extend along the Z-axis direction. A Z-axis moving plate 26 is connected to a front surface side of the pair of Z-axis guide rails 24 in such a manner as to be slidable along the pair of Z-axis guide rails 24.

In addition, a screw shaft 28 extending along the Z-axis direction is disposed between the pair of Z-axis guide rails 24. A motor 30 for rotating the screw shaft 28 is connected to one end part of the screw shaft 28. On a surface of the screw shaft 28 formed with a spiral groove, a nut section (not illustrated) for accommodating a ball that rolls on the surface of the rotating screw shaft 28 is provided, to constitute a ball screw.

In other words, when the screw shaft 28 is rotated, the ball is circulated in the nut section, and the nut section is moved along the Z-axis direction. In addition, the nut section is fixed to a back surface side of the Z-axis moving plate 26. Therefore, when the screw shaft 28 is rotated by the motor 30, the Z-axis moving plate 26 is moved along the Z-axis direction together with the nut section.

A cutting unit (processing unit) 32 is fixed to a lower part of the Z-axis moving plate 26. The cutting unit 32 has a cylindrical spindle housing 34 of which the longitudinal direction is parallel to the Y-axis direction. A columnar spindle (not illustrated) of which the longitudinal direction is parallel to the Y-axis direction is accommodated in the spindle housing 34. The spindle is supported by the spindle housing 34 in a rotatable manner.

A tip part of the spindle protrudes to outside of the spindle housing 34, and a cutting blade 36 having an annular cutting edge is mounted to the tip part. In addition, a base end part of the spindle is connected to a cutting blade rotational drive source (not illustrated) such as a motor incorporated in the spindle housing 34. When the cutting blade rotational drive source is operated, the cutting blade 36 is rotated around a rotational axis extending along the Y-axis direction together with the spindle.

In addition, an imaging unit 38 is fixed to a lower part of the Z-axis moving plate 26, at a position adjacent to the cutting unit 32 in the X-axis direction. The imaging unit 38 has, for example, a light source such as a light emitting diode (LED), an objective lens, and an imaging element such as a charge coupled device (CCD) image sensor or a complementary metal oxide semiconductor (CMOS) image sensor.

Further, a cover 40 covering the holding table 10, the support structure 12, and the like is provided on the upper side of the base 4. Note that, in FIG. 1, for convenience' sake, only sides of the cover 40 are indicated by alternate long and short dash lines. In addition, a touch panel 42 is provided at a side surface of the cover 40.

The touch panel 42 includes, for example, a tough sensor functioning as an input unit for inputting an instruction from an operator to the cutting apparatus 2, and a display as an informing unit for informing the operator of various kinds of information. The touch sensor is, for example, a capacitance type touch sensor or a resistance film type touch sensor. In addition, the display is, for example, a liquid crystal display or an organic electro luminescence (EL) display.

Operations of the above-described constituent elements of the cutting apparatus 2 are controlled by a control unit 44 incorporated in the cutting apparatus 2. The control unit 44 has, for example, a processing section that generates signals for controlling the constituent elements of the cutting apparatus 2, and a storage section that stores various kinds of information (data, programs, etc.) used in the processing section.

The function of the processing section is implemented, for example, by a central processing unit (CPU) that reads and executes a program stored in the storage section. In addition, the function of the storage section is implemented by at least one of a semiconductor memory such as a dynamic random access memory (DRAM), a static random access memory (SRAM), and a NAND-type flash memory, and a magnetic storage device such as a hard disk drive (HDD).

For example, the storage section stores a specific value (for example, 1 mm) of a lower limit processing width (reference width) adopted at the time of carrying out edge trimming on the workpiece 11. In addition, the processing section causes, for example, the touch panel 42 to display an input screen for inputting information necessary to set a processing trajectory of edge trimming to be carried out on the workpiece 11.

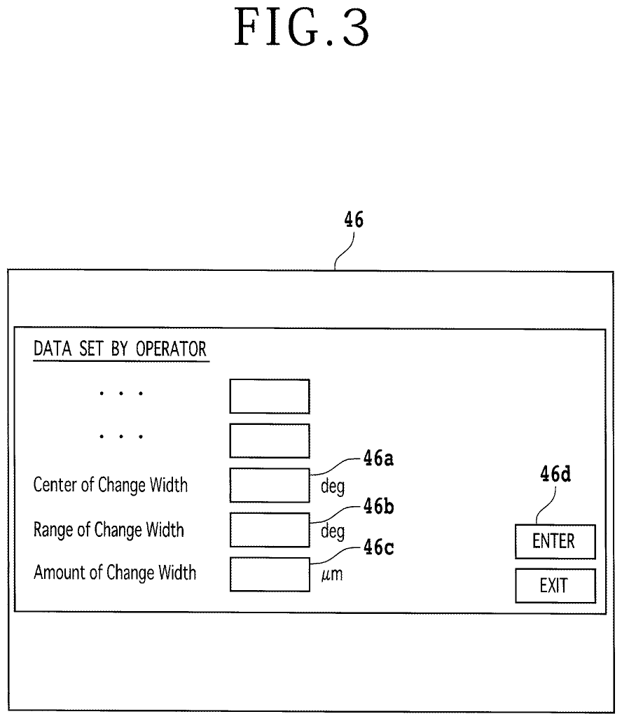

FIG. 3 is a diagram schematically depicting an example of such an input screen. The input screen 46 depicted in FIG. 3 includes a plurality of fields 46a, 46b, and 46c into which information necessary to set the processing trajectory is inputted. Specifically, the field 46a is a field for inputting information indicative of a position to be a reference at the time of edge trimming (a rotational angle of the holding table 10 necessary to match the position of the notch 11c of the workpiece 11 with the processing point of edge trimming).

In addition, the field 46b is a field for inputting information indicative of a range within which the processing width of edge trimming is widened compared to the reference width (a rotational angle of the holding table 10 centered at the position of the notch 11c). Besides, the field 46c is a field for inputting the difference (increase width) between the processing width of edge trimming at a position (the position of the notch 11c) to be a reference at the time of edge trimming and the reference width.

When the operator touches any one of the plurality of fields 46a, 46b, and 46c, the processing section of the control unit 44 causes the touch panel 42 to display numeric keys (not illustrated). As a result, the operator can input a specific numerical value to each of the plurality of fields 46a, 46b, and 46c by use of the numeric keys. When the operator touches an enter icon 46d displayed on the input screen 46 after inputting the numerical values, the respective numerical values are inputted to the control unit 44.

When information necessary to set the processing trajectory of edge trimming to be carried out on the workpiece 11 is inputted to the control unit 44, the processing section of the control unit 44 sets the processing trajectory of edge trimming to be carried out on the workpiece 11. The processing trajectory is set such that the processing width of the peripheral part of the workpiece 11 is narrowed as spaced more from the position of the notch 11c in a predetermined range centered at the position of the notch 11c and that the processing width of the peripheral part of the workpiece 11 is equal to the reference width outside the predetermined range.

In addition, the processing section of the control unit 44 controls the constituent elements of the cutting apparatus 2 such that edge trimming for the workpiece 11 is carried out in a state in which the processing point is positioned in the Y-axis direction as viewed from the center of the holding surface of the holding table 10. In short, during edge trimming, the processing section of the control unit 44 rotates the holding table 10 and moves the cutting unit 32 along the Y-axis direction, but does not move the holding table 10 along the X-axis direction.

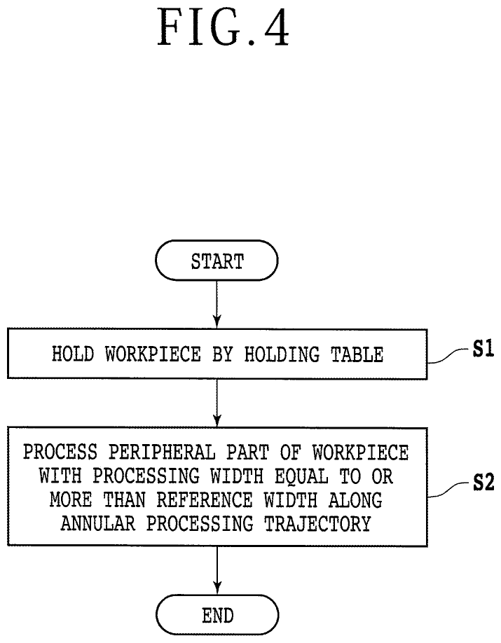

FIG. 4 is a flow chart schematically depicting an example of the processing method for the workpiece 11 in a processing apparatus such as the cutting apparatus 2. In this method, first, the workpiece 11 is held by the holding table 10 (holding step: S1). For example, in a state in which the center of the workpiece 11 and the center of the holding surface of the holding table 10 coincide with each other on a plane (XY plane) parallel to the X-axis direction and the Y-axis direction, the suction source connected to the suction passage formed inside the holding table 10 is operated.

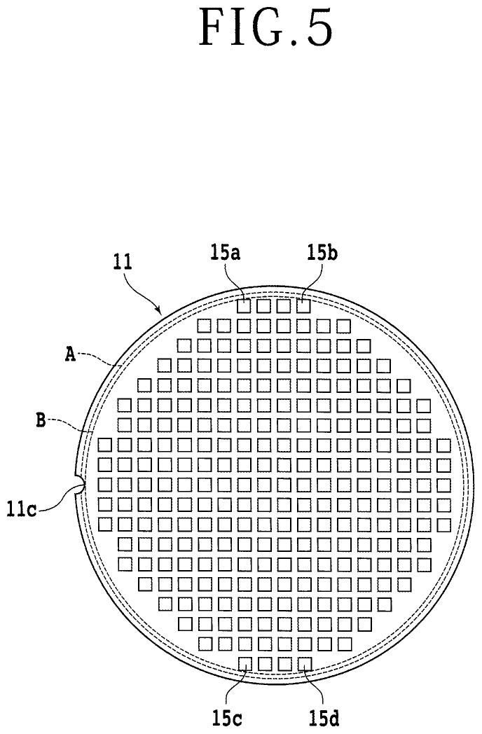

Next, the peripheral part of the workpiece 11 is processed with a processing width equal to or more than the above-described reference width along the annular processing trajectory (processing step: S2). The processing trajectory is set based on the various kinds of information inputted through the touch panel 42 and the like as described above. In this regard, description will be made referring to FIGS. 5 to 7.

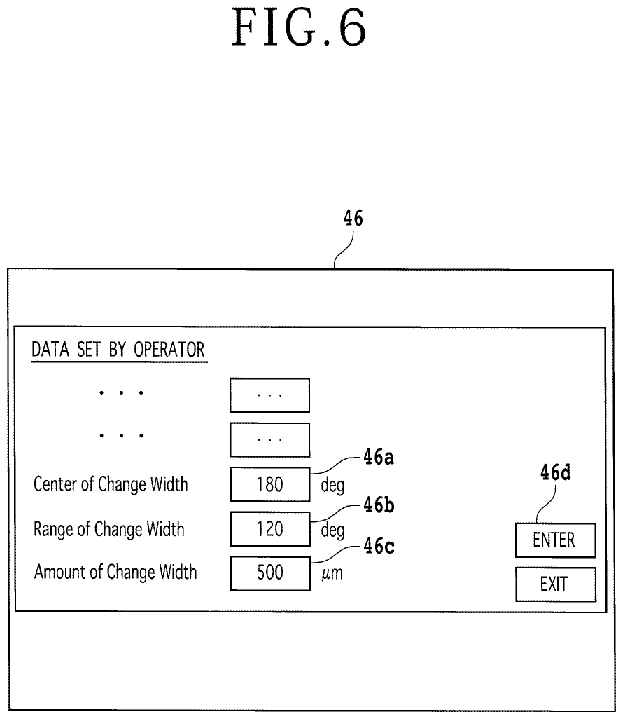

FIG. 5 is a top plan view schematically depicting the workpiece 11 placed on the holding table 10. In addition, a broken line A depicted in FIG. 5 represents a concentric circle of the periphery (exclusive of the notch 11c) of the workpiece 11, the radius of the concentric circle being the length (reference length) obtained by subtracting the above-described reference width from the radius of the workpiece 11. FIG. 6 is a diagram schematically depicting an example of the input screen on which information necessary to set the processing trajectory of edge trimming to be carried out on the workpiece 11 has been inputted.

Specifically, in FIG. 5, the notch 11c of the workpiece 11 is positioned in a direction opposite to the Y-axis direction as viewed from the center of the holding surface of the holding table 10. In addition, in edge trimming for the workpiece 11 in the cutting apparatus 2, as described above, the processing point is positioned in the Y-axis direction as viewed from the center of the holding surface of the holding table 10. Therefore, the rotational angle of the holding table 10 necessary for matching the position of the notch 11c with the processing point of edge trimming is 180°, and this value is inputted to the field 46a on the input screen 46 depicted in FIG. 6.

Note that such confirmation of the position of the notch 11c is carried out, for example, based on an image formed by imaging of the workpiece 11 by the imaging unit 38. In other words, the operator can input a suitable numerical value to the field 46a by referring to this image or the like.

Alternatively, the position of the notch 11c of the workpiece 11 may first be confirmed before the workpiece 11 is conveyed in to the holding table 10, and then the workpiece 11 may be conveyed in to the holding table 10 such that the notch 11c is positioned in a predetermined direction as viewed from the center of the holding table 10. In the case where the position of the notch 11c as viewed from the center of the holding table 10 is thus predetermined, the input screen 46 may not include the field 46a.

In addition, in FIG. 5, the width of the notch 11c of the workpiece 11 in the radial direction of the holding surface of the holding table 10 is, for example, longer than the above-described reference width by 200 to 400 μm. In such a case, as the above-described increase width necessary to remove the notch 11c depicted in FIG. 5, for example, 500 μm is inputted to the field 46c on the input screen 46 depicted in FIG. 6. Note that a broken line B depicted in FIG. 5 represents a concentric circle of the periphery (exclusive of the notch 11c) of the workpiece 11, the radius of the concentric circle being a length (shortest length) obtained by subtracting the above-described reference width and the above-described increase width from the radius of the workpiece 11.

In addition, in FIG. 5, the broken line B slightly overlaps corners of devices 15a, 15b, 15c, and 15d formed on the workpiece 11. In such a case, to prevent damaging of the devices 15a, 15b, 15c, and 15d due to edge trimming, the processing width of edge trimming for regions in the vicinity of the devices 15a, 15b, 15c, and 15d is preferably the above-described reference width. Therefore, for example, 120° is inputted to the field 46b on the input screen 46 depicted in FIG. 6.

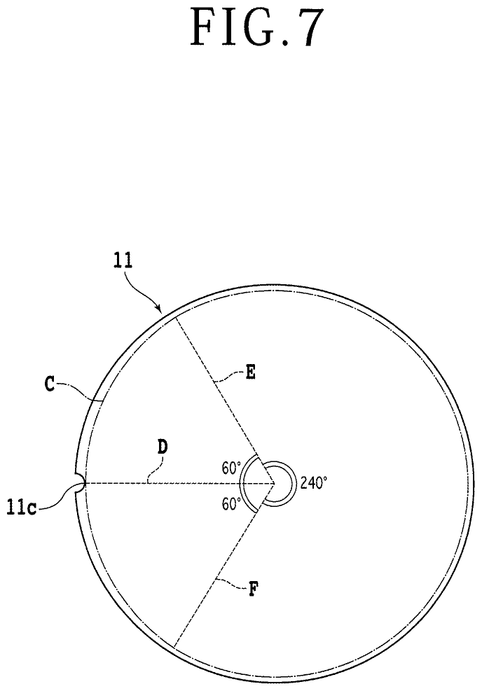

FIG. 7 is a top plan view schematically depicting the workpiece 11 on which an inner circumference (indicated by an alternate long and short dash line C) of the processing trajectory of edge trimming set based on the various kinds of information depicted in FIG. 6 is overlaid. In other words, in the processing step (S2), the peripheral part of the workpiece 11 positioned on an outer side of the alternate long and short dash line C depicted in FIG. 7 is processed.

Note that, in FIG. 7, for convenience' sake, the plurality of devices 15 formed on the workpiece 11 are omitted. In addition, a broken line D depicted in FIG. 7 is a line segment which connects the center of the workpiece 11 and the alternate long and short dash line C and which is parallel to a straight line passing the center of the workpiece 11 and the position of the notch 11c. In other words, the length of the broken line D is equal to the above-described shortest length.

In addition, a broken line E and a broken line F depicted in FIG. 7 are each a line segment which connects the center of the workpiece 11 and the alternate long and short dash line C and the length of which is equal to the above-described reference length. Besides, an acute angle formed between the broken line D and the broken line E and an acute angle formed between the broken line D and the broken line F are each 60°.

In addition, the distance between the center of the workpiece 11 and a point on the alternate long and short dash line C located at a boundary of a fan-shaped region with a center angle of 60° surrounded by the alternate long and short dash line C, the broken line D, and the broken line E or F is longer as the point is spaced more from the position of the notch 11c. Besides, the distance between the center of the workpiece 11 and a point on the alternate long and short dash line C located at a boundary of a fan-shaped region with a center angle of 240° surrounded by the alternate long and short dash line C, the broken line E, and the broken line F is constant (the above-described reference length).

In other words, the inner circumference (indicated by the alternate long and short dash line C) of the processing trajectory has the distance from the center of the workpiece 11 becoming longer as spaced more from the position of the notch 11c, in a range of 120° of the rotational angle of the holding table 10 centered at the position of the notch 11c. In addition, the inner circumference (alternate long and short dash line C) of the processing trajectory has the distance from the center of the workpiece 11 being the same outside this range (in the remaining range of 240°).

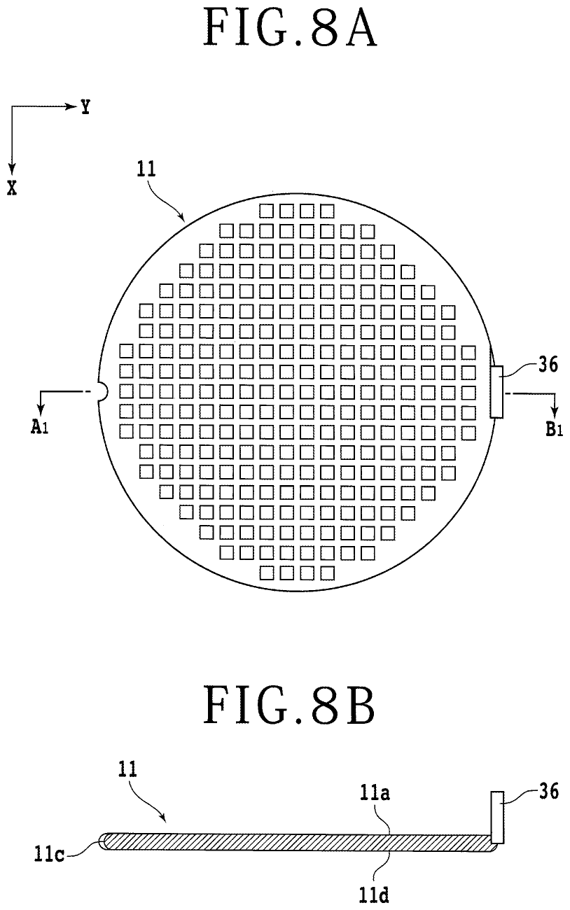

In the processing step (S2), edge trimming is carried out on the workpiece 11 along the processing trajectory. An example of the edge trimming will be described referring to FIGS. 8A, 8B, 9A, 9B, 10A, 10B, 11A, 11B, 12A, and 12B. Note that FIGS. 8A, 9A, 10A, 11A, and 12A are each a top plan view schematically depicting the workpiece 11 undergoing edge trimming, and FIGS. 8B, 9B, 10B, 11B, and 12B are sectional views schematically depicting sections of the workpiece 11, taken along lines A_{N}B_{N} (N is an integer of equal to or less than 5) depicted in FIGS. 8A, 9A, 10A, 11A, and 12A, respectively.

In addition, in FIGS. 8A, 9A, 10A, 11A, and 12A, for convenience' sake, an upper surface of the cutting blade 36 is schematically depicted. Besides, in FIGS. 8B, 9B, 10B, 11B, and 12B, for convenience' sake, a side surface of the cutting blade 36 is schematically depicted. In addition, as the cutting blade 36, a cutting blade having a width larger than the sum of the above-described reference width and the above-described increase width is used.

At the time of carrying out edge trimming on the workpiece 11, first, the X-axis direction moving mechanism moves the holding table 10 in the X-axis direction such that the cutting blade 36 is spaced from the workpiece 11. Next, the Y-axis direction moving mechanism 14 moves the cutting unit 32 in the Y-axis direction such that a region of the peripheral part of the workpiece 11 located in the Y-axis direction as viewed from the center of the workpiece 11 is disposed in the X-axis direction as viewed from the cutting blade 36.

In this instance, the distance between this region and the center of the workpiece 11 is adjusted to be the above-described reference length. Next, the Z-axis direction moving mechanism 22 lowers the cutting unit 32 such that the lowest end of the cutting blade 36 is located at a position below the front surface 11a of the workpiece 11 and above the back surface 11d. Subsequently, while the cutting blade rotational drive source is operated to rotate the cutting blade 36, the cutting blade 36 is caused to cut into the workpiece 11.

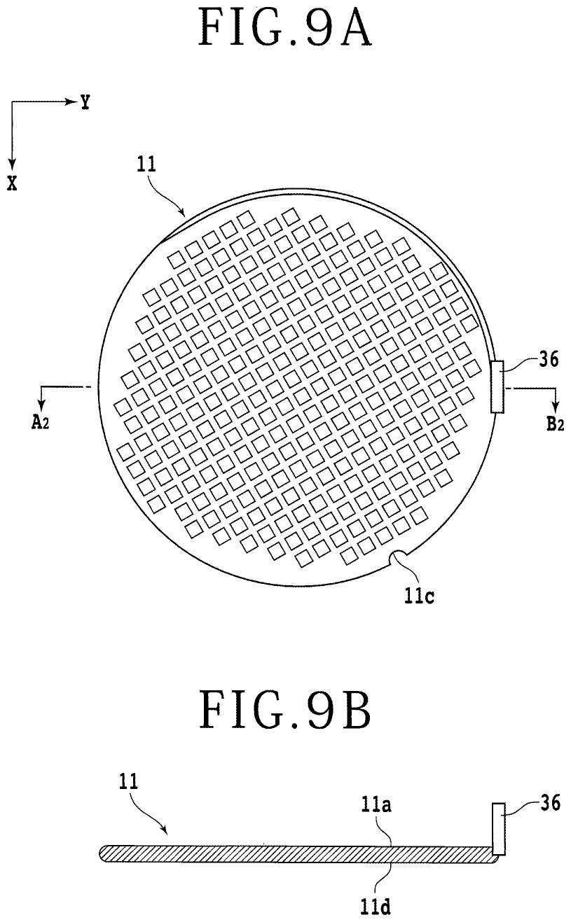

Specifically, the X-axis direction moving mechanism moves the holding table 10 along the X-axis direction until the lowest end of the cutting blade 36 reaches the region of the peripheral part of the workpiece 11 located in the Y-axis direction as viewed from the center of the workpiece 11 (see FIGS. 8A and 8B). Next, while the cutting blade 36 is being rotated, the holding table rotational drive source rotates the holding table 10 by 120° (see FIGS. 9A and 9B).

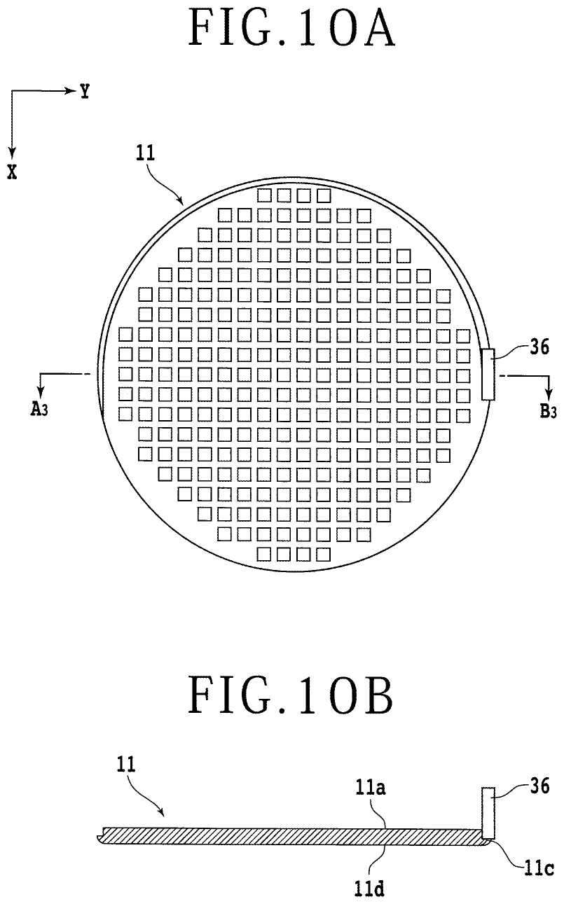

Subsequently, while the cutting blade 36 and the holding table 10 are being rotated, the Y-axis direction moving mechanism 14 adjusts the position of the cutting unit 32 such that the cutting blade 36 approaches the center of the workpiece 11. Specifically, the Y-axis direction moving mechanism 14 causes the cutting unit 32 to gradually approach the center of the workpiece 11 such that the distance between the center of the workpiece 11 and the cutting blade 36 becomes the above-described shortest length at the timing when the holding table 10 has further been rotated by 60° (see FIGS. 10A and 10B).

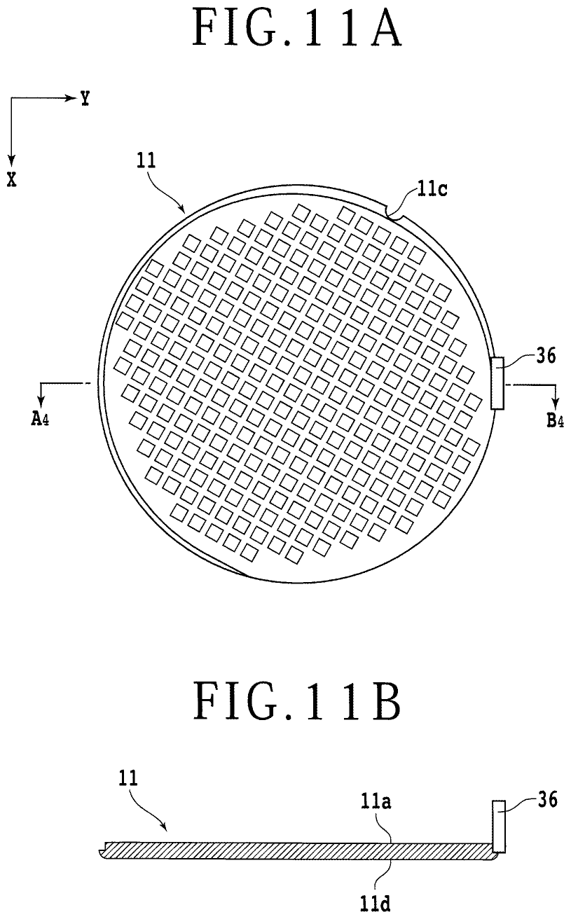

After the distance between the center of the workpiece 11 and the cutting blade 36 is set to the above-described shortest length, while the cutting blade 36 and the holding table 10 are being rotated, the Y-axis direction moving mechanism 14 adjusts the position of the cutting unit 32 such that the cutting blade 36 is spaced away from the center of the workpiece 11. Specifically, the Y-axis direction moving mechanism 14 causes the cutting unit 32 to be gradually spaced away from the center of the workpiece 11 such that the distance between the center of the workpiece 11 and the cutting blade 36 becomes the above-described reference length at the timing when the holding table 10 has further been rotated by 60° (see FIGS. 11A and 11B).

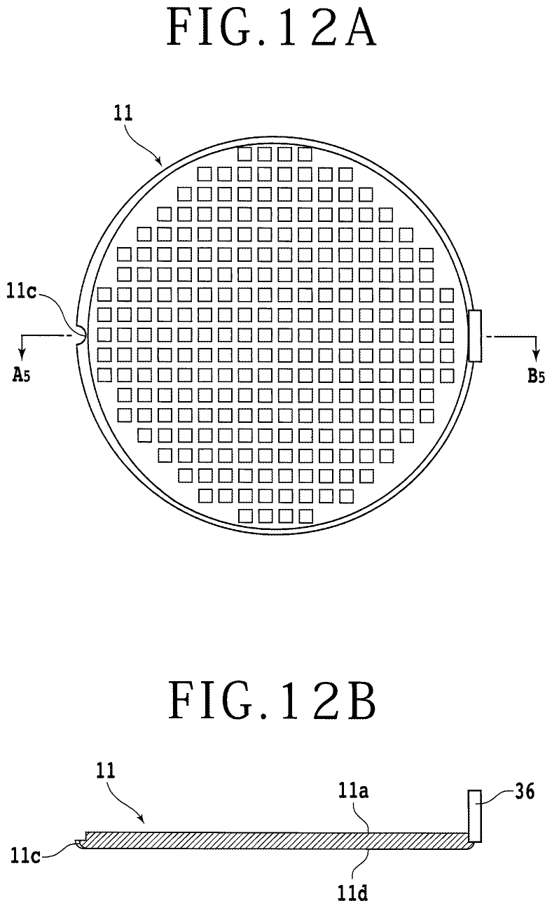

After the distance between the center of the workpiece 11 and the cutting blade 36 is set to the above-described reference length, while the cutting blade 36 and the holding table 10 are being rotated, the distance between the center of the workpiece 11 and the cutting blade 36 is maintained. Specifically, the Y-axis direction moving mechanism 14 does not move the cutting unit 32 until the holding table 10 is rotated further by 120° (see FIGS. 12A and 12B).

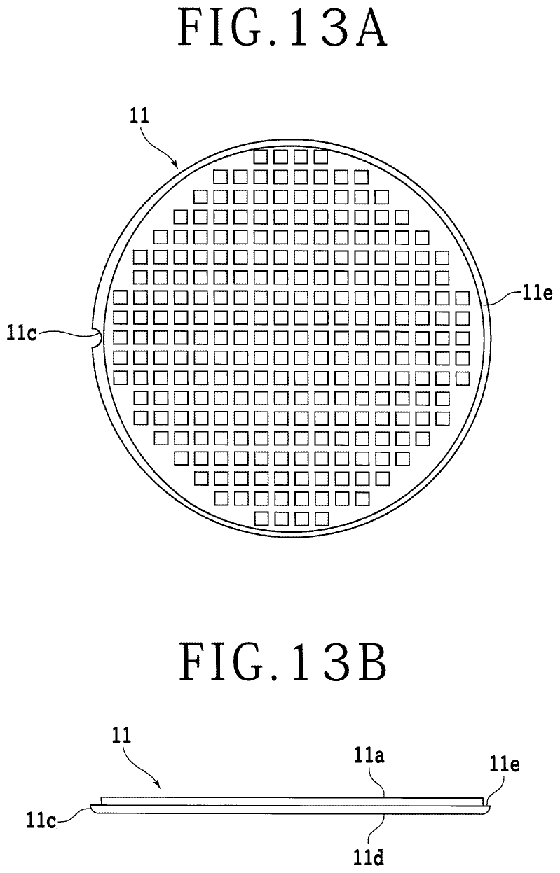

By the above operations, edge trimming on the workpiece 11 is completed. As a result, the workpiece 11 formed with a step 11e at the peripheral part thereof by edge trimming is obtained as depicted in FIGS. 13A and 13B. Note that FIG. 13A is a top plan view schematically depicting the workpiece 11 after edge trimming, and FIG. 13B is a side view schematically depicting the workpiece 11 after edge trimming.

In the method depicted in FIG. 4, the processing trajectory at the time of processing the peripheral part of the workpiece 11 is set such that the processing width of the peripheral part of the workpiece 11 is narrowed as spaced more from the position of the notch 11c in a predetermined range centered at the position of the notch 11c and that the processing width of the peripheral part of the workpiece 11 is equal to the reference width (lower limit of the processing width) outside the predetermined range.

As a result, in the method depicted in FIG. 4, the processing width at a position far from the position of the notch 11c is narrow, and therefore, the proportion of devices 15 damaged by edge trimming is reduced or set to zero. In addition, in this method, since the processing width at the position of the notch 11c is widened most, the probability that cracks are generated in the workpiece 11 after the back surface 11d side of the workpiece 11 is ground can be lowered.

Note that the above-described method is one mode of the present invention, and the method of the present invention is not limited to the above-described method. For example, in the processing step (S2) of the above-described method, edge trimming is carried out such that a part on the back surface 11d side of the peripheral part of the workpiece 11 is left, but in the processing step of the method of the present invention, the whole part of the peripheral part of the workpiece 11 may be removed.

In other words, in the processing step of the method of the present invention, edge trimming may be carried out in such a manner as to form a side surface orthogonal to the front surface 11a and the back surface 11d of the workpiece 11, without forming the step 11e at the peripheral part of the workpiece 11.

Such edge trimming is, for example, carried out by processing the peripheral part of the workpiece 11, as described above, in a state in which the lowest end of the cutting blade 36 is positioned below the back surface 11d of the workpiece 11.

Note that, in this case, it is preferable that a dicing tape be attached to the back surface 11d side of the workpiece 11. In other words, it is preferable to carry out edge trimming on the workpiece 11 in a state in which the workpiece 11 is held by the holding table 10 through the dicing tape.

In addition, in the processing step (S2) of the above-described method, the workpiece 11 is processed by use of the cutting blade 36, but in the processing step of the method of the present invention, the workpiece 11 may be processed by use of a laser beam.

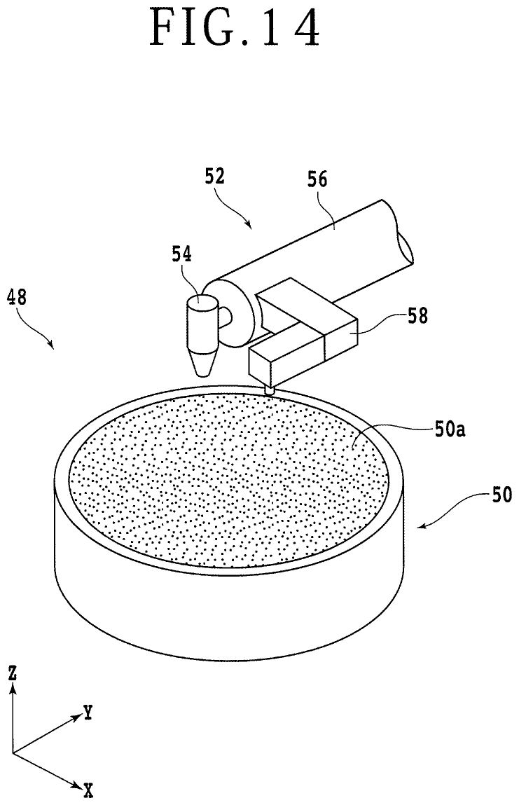

FIG. 14 is a perspective view schematically depicting an example of a laser applying apparatus for carrying out a processing step by use of a laser beam. Note that an X-axis direction, a Y-axis direction, and a Z-axis direction depicted in FIG. 14 correspond respectively to the X-axis direction, the Y-axis direction, and the Z-axis direction depicted in FIG. 1.

The laser applying apparatus 48 depicted in FIG. 14 has a holding table 50. The holding table 50 has a disk-shaped porous plate 50a exposed to the upper side. An upper surface of the porous plate 50a is substantially flat, and becomes a holding surface that holds the workpiece 11 thereon.

Inside the holding table 50, there is formed a suction passage (not illustrated) having one end connected to a suction source (not illustrated) such as an ejector provided outside the holding table 50. The other end of the suction passage reaches the porous plate 50a. When the suction source is operated in a state in which the workpiece 11 is placed on the holding surface with the back surface 11d set on the lower side, the workpiece 11 is held by the holding table 50 under suction.

Further, the holding table 50 is connected to an X-axis direction moving mechanism (not illustrated) and a Y-axis direction moving mechanism (not illustrated). When the X-axis direction moving mechanism and/or the Y-axis direction moving mechanism is operated, the holding table 50 is moved in the X-axis direction and/or the Y-axis direction. In addition, the holding table 50 is connected to a rotational drive source (not illustrated). When the rotational drive source is operated, the holding table 50 is rotated around a rotational axis which passes through the center of the holding surface and which extends along the Z-axis direction.

Above the holding table 50, a head 54 of a laser beam applying unit (processing unit) 52 is provided. The head 54 is provided at a tip (one end) part of a connection section 56 extending in the Y-axis direction. Note that the head 54 accommodates an optical system such as a condenser lens and a mirror, and the connection section 56 accommodates an optical system such as a mirror and/or a lens.

In addition, the other end part of the connection section 56 is connected to a Z-axis direction moving mechanism (not illustrated). When the Z-axis direction moving mechanism is operated, the head 54 and the connection section 56 are moved in the Z-axis direction. The laser beam applying unit 52 has a laser oscillator (not illustrated) that generates a laser beam of such a wavelength (for example, 365 nm) as to be absorbed in the workpiece 11 or such a wavelength (for example, 1,064 nm) as to be transmitted through the workpiece 11.

The laser oscillator has a laser medium such as, for example, Nd:YAG. When a laser beam is generated in the laser oscillator, the laser beam is applied toward directly below the head 54 through the optical systems accommodated in the connection section 56 and the head 54.

Further, at a side part of the connection section 56, an imaging unit 58 capable of imaging the holding surface side of the holding table 50. The imaging unit 58 has, for example, a light source such as an LED, an objective lens, and an imaging element such as a CCD image sensor or a CMOS image sensor.

In the laser applying apparatus 48, edge trimming is carried out on the workpiece 11 by use of the laser beam of such a wavelength as to be absorbed in the workpiece 11 or such a wavelength as to be transmitted through the workpiece 11. Specifically, first, the workpiece 11 is held by the holding table 50 (holding step: S1).

For example, in the XY plane, in a state in which the center of the workpiece 11 and the center of the holding surface of the holding table 50 coincide with each other, the suction source connected to the suction passage formed inside the holding table 50 is operated. As a result, for example, as depicted in FIG. 5, the workpiece 11 is placed on the holding table 50 in a state in which the notch 11c is positioned in a direction opposite to the Y-axis direction as viewed from the center of the holding table 50.

In the case where the laser beam of such a wavelength as to be absorbed in the workpiece 11 is used, for example, the processing step (S2) is carried out in the following order. First, the X-axis direction moving mechanism, the Y-axis direction moving mechanism, and the rotational drive source adjust the position of the holding table 50 holding the workpiece 11 such that the head 54 of the laser beam applying unit 52 is positioned directly above a region of the peripheral part of the workpiece 11 located in the Y-axis direction as viewed from the center of the workpiece 11.

Next, the laser beam of such a wavelength as to be absorbed in the workpiece 11 is applied to the workpiece 11. As a result, ablation of the material constituting the chamfered peripheral part of the workpiece 11 occurs. In this instance, the laser beam is adjusted, for example, such that its width along the Y-axis direction is wider than the sum of the above-described reference width and the above-described increase width. In addition, the distance between the center of the workpiece 11 and the laser beam applied to the workpiece 11 is adjusted to be equal to the above-described reference length.

Next, as has been described referring to FIGS. 8A, 8B, 9A, 9B, 10A, 10B, 11A, 11B, 12A, 12B, and the like, while the Y-axis direction moving mechanism and the rotational drive source are moving the holding table 50, the laser beam applying unit 52 applies the laser beam of such a wavelength as to be absorbed in the workpiece 11. As a result, as depicted in FIGS. 13A and 13B, the workpiece 11 formed with the step 11e at the peripheral part thereof by edge trimming is obtained.

In addition, in the case where the laser beam of such a wavelength as to be transmitted through the workpiece 11 is used, for example, the processing step (S2) is carried out in the following order. First, the X-axis direction moving mechanism, the Y-axis direction moving mechanism, and the rotational drive source adjust the position of the holding table 50 holding the workpiece 11 such that the head 54 of the laser beam applying unit 52 is positioned directly above the region of the peripheral part of the workpiece 11 located in the Y-axis direction as viewed from the center of the workpiece 11.

Next, the laser beam of such a wavelength as to be transmitted through the workpiece 11 is applied to the workpiece 11. As a result, the structure of the material constituting the chamfered peripheral part of the workpiece 11 is modified due to multiphoton absorption. In this instance, the laser beam is adjusted such that the light concentrating point thereof is positioned inside the workpiece 11. In addition, the distance between the center of the workpiece 11 and the laser beam applied to the workpiece 11 is adjusted to be equal to the above-described reference length.

Subsequently, as has been described referring to FIGS. 8A, 8B, 9A, 9B, 10A, 10B, 11A, 11B, 12A, 12B, and the like, while the Y-axis direction moving mechanism and the rotational drive source are moving the holding table 50, the laser beam applying unit 52 applies the laser beam of such a wavelength as to be transmitted through the workpiece 11. As a result, the workpiece 11 formed with an annular modified layer inside a peripheral end part thereof is obtained.

Next, an external force is exerted on the workpiece 11, thereby breaking the workpiece 11 along the annular modified layer. For example, by grinding the back surface 11d side of the workpiece 11, cracks are developed in the thickness direction of the workpiece 11 from the annular modified layer, to thereby separate the central part of the workpiece 11 and the chamfered peripheral end part. As a result, the workpiece 11 having undergone edge trimming is obtained.

Note that adjustment of the position of the processing point in the laser beam applying apparatus 48 (the position of the workpiece 11 at which the laser beam is applied) may be carried out by adjusting the optical systems accommodated in the laser beam applying unit 52. In other words, adjustment of the processing point may be carried out by adjusting the inclination or the like of the mirror and/or the lens accommodated in the laser beam applying unit 52.

Other than the above points, the configurations, the methods, and the like according to the above-described embodiments may be modified as required insofar as the modification does not depart from the range of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus for processing a disk-shaped workpiece formed with a notch, the processing apparatus comprising:
a holding table that holds the workpiece;
a processing unit that processes the workpiece held by the holding table; and
a control unit that controls the processing unit in such a manner as to process a peripheral part of the workpiece with a processing width equal to or more than a reference width along an annular processing trajectory,
wherein the processing trajectory is set such that the processing width of the peripheral part of the workpiece is narrowed as spaced more from a position of the notch in a predetermined range including the position of the notch and that the processing width of the peripheral part of the workpiece is equal to the reference width outside the predetermined range.

2. The processing apparatus according to claim 1, further comprising:
an input unit through which to input information for setting the processing trajectory to the control unit,
wherein the information includes an increase width of the processing width from the reference width at the position of the notch and the predetermined range.

3. The processing apparatus according to claim 1, wherein the processing unit has an annular cutting blade attached to a spindle.

4. The processing apparatus according to claim 2, wherein the processing unit has an annular cutting blade attached to a spindle.

5. The processing apparatus according to claim 1, wherein the processing unit has a laser oscillator that generates a laser beam of such a wavelength as to be absorbed in the workpiece.

6. The processing apparatus according to claim 2, wherein the processing unit has a laser oscillator that generates a laser beam of such a wavelength as to be absorbed in the workpiece.

7. The processing apparatus according to claim 1, wherein the processing unit has a laser oscillator that generates a laser beam of such a wavelength as to be transmitted through the workpiece.

8. The processing apparatus according to claim 2, wherein the processing unit has a laser oscillator that generates a laser beam of such a wavelength as to be transmitted through the workpiece.

9. A processing method for processing a disk-shaped workpiece formed with a notch, the processing method comprising:
a holding step of holding the workpiece by a holding table; and
a processing step of processing a peripheral part of the workpiece with a processing width equal to or more than a reference width along an annular processing trajectory,
wherein the processing trajectory is set such that the processing width of the peripheral part of the workpiece is narrowed as spaced more from a position of the notch in a predetermined range including the position of the notch and that the processing width of the peripheral part of the workpiece is equal to the reference width outside the predetermined range.
